(19) United States
(12) Patent Application Publication
(10) Pub. No.: US 2017/0047495 A1
(43) Pub. Date: Feb. 16, 2017

(54) Optoelectronic Semiconductor Device With Ferromagnetic Domains

(71) Applicant: Sensor Electronic Technology, Inc., Columbia, SC (US)

(72) Inventors: Michael Shur, Latham, NY (US); Alexander Dobrinsky, Loudonville, NY (US)

(73) Assignee: Sensor Electronic Technology, Inc., Columbia, SC (US)

(21) Appl. No.: 15/228,149

(22) Filed: Aug. 4, 2016

Related U.S. Application Data
(60) Provisional application No. 62/203,508, filed on Aug. 11, 2015.

(51) Int. Cl. H01L 33/62; H01L 33/42; H01L 33/14; H01L 33/32; H01L 33/06; H01L 33/12

(52) U.S. Cl. CPC H01L 33/62; H01L 33/06; H01L 33/12; H01L 33/145; H01L 33/32; H01L 33/42; H01L 2933/0066

(57) ABSTRACT

An optoelectronic semiconductor device with one or more ferromagnetic domains and method for processing an optoelectronic semiconductor device and/or devices with the ferromagnetic domain(s) is described. In one embodiment, the optoelectronic semiconductor device can include a semiconductor structure having a substrate, an n-type contact layer formed over the substrate, an active layer formed over the n-type contact layer, and a p-type contact layer formed over the active layer; and at least one ferromagnetic domain located on the semiconductor structure. The method for processing can include moving and/or assembling the optoelectronic semiconductor device(s) into a system.

### REFERENCE TO RELATED APPLICATIONS

The present patent application claims the benefit of U.S. Provisional Application No. 62/203,508, which was filed on 11 Aug. 2015, and which is hereby incorporated by reference.

### TECHNICAL FIELD

The present invention relates generally to semiconductor devices, and more particularly, to an optoelectronic semiconductor device with ferromagnetic domains and a method for using a magnetic force to process the semiconductor device.

### BACKGROUND ART

Semiconductor devices such as, for example, optoelectronic semiconductor devices, can be manipulated by a variety of approaches including human manipulation and automated manipulation through the use of robotic systems. Manipulation or processing of thin semiconductor films that contain optoelectronic semiconductor devices can be complicated and can result in damaging semiconductor components used in the devices. For instance, individual semiconductor structures (e.g., dies or wafers) may be relatively thin and difficult to handle with equipment used for processing the semiconductor structures. As a result, “carrier” dies or wafers may be attached to the actual semiconductor structures that include the active and passive components of operative semiconductor devices. These carrier dies and wafers, which can be referred to as “carrier substrates,” do not typically include any active or passive components of a semiconductor device to be formed. Generally, the carrier substrates increase the overall thickness of the semiconductor structures and facilitate handling of the structures by providing structural support to the relatively thinner semiconductor structures. In addition, the carrier substrates facilitate the handling of the active and/or passive components in the semiconductor structures by processing equipment. While carrier substrates are useful, the attachment process of the carrier substrates to the semiconductor structures can affect the properties of the semiconductor films. For example, carrier substrates that have been attached to the semiconductor structures with epoxy require care in order to remove the semiconductor die.

Other approaches have been used in the processing of these thin film semiconductor devices. One approach entails using a suction mechanism for lifting off the semiconductor films. A suction mechanism typically complicates the processing of these thin film semiconductor devices. In addition, a suction mechanism cannot easily be employed in metal-organic chemical vapor deposition chambers. Also, this suction approach is not very useful for further manipulation of these semiconductor devices, such as optoelectronic semiconductor devices, for assembly into electronic circuits.

### SUMMARY OF THE INVENTION

This Summary Of The Invention introduces a selection of certain concepts in a brief form that are further described below in the Detailed Description Of The Invention. It is not intended to exclusively identify key features or essential features of the claimed subject matter set forth in the Claims, nor is it intended as an aid in determining the scope of the claimed subject matter.

Aspects of the present invention can obviate one or more of the shortcomings of the aforementioned approaches to handling thin film semiconductor devices, such as optoelectronic semiconductor devices. In one embodiment, an optoelectronic semiconductor device utilizes ferromagnetic domains that can be embedded in, or on the device. In this manner, magnetic forces generated from a magnetic field can be used to process the optoelectronic semiconductor device singly or as a set of optoelectronic semiconductor devices assembled into a system.

In one embodiment, an optoelectronic semiconductor device with ferromagnetic domains can be manipulated after an ablation operation to separate the device from a substrate, e.g., by utilizing at least one magnet such as an electromagnet. For example, a first electromagnet can be used to lift-off the optoelectronic semiconductor device away from the substrate. A second electromagnet can be attached to another side of the optoelectronic semiconductor device. The first electromagnet can be detached, so that the second electromagnet can move the optoelectronic device to another location for assembly into a system of optoelectronic semiconductor devices, or for use as a template for subsequent epitaxial growth of other semiconductor structures that can form the device.

In another embodiment, the optoelectronic semiconductor device(s) with ferromagnetic domains can be moved by a robotic device, such as a robotic arm, having an electromagnet for further formation of the device(s) or assembly into a system of devices. For example, the optoelectronic semiconductor device(s) with ferromagnetic domains can be guided over a pair of electrodes with the robotic arm to form a flip-chip configuration, or more complex configurations.

In another embodiment, the optoelectronic semiconductor device(s) with the ferromagnetic domains can be used as an electrical connector with a connector board in a circuit component self-assembly. For example, the optoelectronic semiconductor device(s) with the ferromagnetic domains can be used to connect with the connector board having input/output connectors with ferromagnetic magnetized domains that are complementary to the domains of the device(s).

A first aspect of the invention provides an optoelectronic semiconductor device, comprising: a semiconductor structure including a substrate, an n-type contact layer formed over the substrate, an active layer formed over the n-type contact layer, and a p-type contact layer formed over the active layer; and at least one ferromagnetic domain located on the semiconductor structure.

A second aspect of the invention provides an optoelectronic semiconductor device, comprising: a substrate; a semiconductor structure formed over the substrate, including an n-type contact layer, an active layer formed over the n-type contact layer, and a p-type contact layer formed over the active layer; a metallic contact to the semiconductor structure located on the substrate about the semiconductor structure; and at least one ferromagnetic domain formed over one of the substrate, the metallic contact, or the semiconductor structure.

A third aspect of the invention provides a method, comprising: fabricating an optoelectronic semiconductor device, wherein the optoelectronic semiconductor device comprises: a semiconductor structure including: a substrate; an n-type contact layer formed over the substrate; an active layer formed over the n-type contact layer; and a p-type contact layer formed over the active layer; and at least one ferromagnetic domain located on the semiconductor structure.

A fourth aspect of the invention provides a semiconductor device, comprising: a first semiconductor structure including an n-type contact and a p-type contact, each contact on an opposing side of the first semiconductor structure, and at least one ferromagnetic domain on one side of the first semiconductor structure containing one of the n-type contact and the p-type contact; and a second semiconductor structure coupled to the first semiconductor structure, the second semiconductor structure including an n-type contact and a p-type contact, each contact on an opposing side of the second semiconductor structure, and at least one ferromagnetic domain on one side of the second semiconductor structure containing one of the n-type contact and the p-type contact, wherein the at least one ferromagnetic domain of the second semiconductor structure is coupled to the at least one ferromagnetic domain of the first semiconductor structure.

A fifth aspect of the invention provides a circuit component self-assembly, comprising: a connector board including a plurality of input/output connectors, each input/output connector having a port and at least one ferromagnetic magnetized domain located about the port; and at least one electrical device having an electrical connector adapted for connection into a port of one of the input/output connectors and at least one ferromagnetic magnetized domain located about the electrical connector, wherein the at least one ferromagnetic magnetized domain of the electrical device is coupled to the at least one ferromagnetic magnetized domain of the input/output connector upon insertion of the electrical connector into the port.

A sixth aspect of the invention provides a method, comprising: obtaining a set of optoelectronic semiconductor devices, each having a semiconductor structure including a substrate, an n-type contact layer formed over the substrate, an active layer formed over the n-type contact layer, and a p-type contact layer formed over the active layer, and at least one ferromagnetic domain located about the semiconductor structure; placing the set of optoelectronic semiconductor devices in proximity to a magnetic force; guiding the set of optoelectronic semiconductor devices over a pair of spaced electrodes with the magnetic force; and releasing the set of optoelectronic semiconductor devices from the magnetic force for placement onto the pair of spaced electrodes.

A seventh aspect of the invention provides a method of forming an optoelectronic semiconductor device, comprising: obtaining a semiconductor structure including a substrate, a sacrificial semiconductor layer formed over the substrate, a supporting semiconductor layer formed over the sacrificial layer, and an n-type contact layer formed over the supporting semiconductor layer, and at least one ferromagnetic domain located within the semiconductor structure; decomposing the sacrificial layer; and lifting-off the semiconductor structure with the supporting semiconductor layer and the n-type contact layer away from the substrate.

The illustrative aspects of the invention are designed to solve one or more of the problems herein described and/or one or more other problems not discussed.

### BRIEF DESCRIPTION OF THE DRAWINGS

These and other features of the disclosure will be more readily understood from the following detailed description of the various aspects of the present invention taken in conjunction with the accompanying drawings that depict various aspects of the invention.

FIG. 1 shows a schematic of an optoelectronic semiconductor device according to the prior art.

FIG. 2 shows a schematic of an optoelectronic semiconductor device having ferromagnetic domains according to an embodiment of the present invention.

FIGS. 3A-3E show a method for processing an optoelectronic semiconductor device having ferromagnetic domains according to an embodiment of the present invention.

FIGS. 4A-4B show a schematic of an optoelectronic semiconductor device with a mesa structure having ferromagnetic domains on an exterior surface of the device, while FIG. 4C shows a set of optoelectronic semiconductor devices depicted on FIGS. 4A-4B according to an embodiment of the present invention.

FIG. 5 shows a schematic of an assembly of an optoelectronic device formed from two optoelectronic semiconductor devices having ferromagnetic domains of each device coupled to each other along with a contact to each device coupled together according to an embodiment of the present invention.

FIG. 6 shows a schematic of an assembly of optoelectronic devices each formed from two optoelectronic semiconductor devices having ferromagnetic domains coupled to a pair of spaced electrodes extending between the devices according to an embodiment of the present invention.

FIG. 7A-7C show a schematic of a circuit component self-assembly with an optoelectronic semiconductor device with ferromagnetic domains used as an electrical connector and a connector board having input/output connectors with ferromagnetic magnetized domains that are complementary to the ferromagnetic domains of the optoelectronic semiconductor device in the form of an electrical connector according to an embodiment of the present invention.

FIG. 8 shows an illustrative flow diagram for fabricating a circuit that includes an optoelectronic semiconductor device having ferromagnetic domains described herein according to the various embodiments of the present invention.

It is noted that the drawings may not be to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

The various embodiments are directed to optoelectronic semiconductor devices having ferromagnetic domains. Other embodiments are directed to a method for processing these optoelectronic semiconductor devices with ferromagnetic domains. This method of processing can include moving these optoelectronic semiconductor devices with a magnetic force generated from a magnet such as an electromagnet. The processing can further include forming these optoelectronic semiconductor devices with additional semiconductor structures through techniques that can include epitaxial growth. Also, the processing can include assembling these optoelectronic semiconductor devices with ferromagnetic domains into various types of systems of optoelectronic devices, where the ferromagnetic domains of the devices can bond together through magnetization of the domains. In one embodiment, the processing of the optoelectronic semiconductor devices with ferromagnetic devices into systems can include attaching electrodes to the devices. The processing of the optoelectronic semiconductor devices can be implemented by an automated system that can include robotic arms with electromagnets, epitaxial growth chambers, workstations, conveyors, and the like. In this manner, a single optoelectronic semiconductor device or a set of devices can be processed. In another embodiment, the optoelectronic semiconductor devices with the ferromagnetic domains can be used as an electrical connector with a connector board in a circuit component self-assembly.

The optoelectronic semiconductor devices with ferromagnetic domains of the various embodiments described herein are suitable for use with a variety of optoelectronic devices. Examples of optoelectronic devices can include, but are not limited to, light emitting devices, light emitting diodes (LEDs), including conventional and super luminescent LEDs, light emitting solid state lasers, laser diodes, photodetectors, photodiodes, and high-electron mobility transistors (HEMTs). These examples of optoelectronic devices can be configured to emit electromagnetic radiation from a light generating structure such as an active region upon application of a bias. The electromagnetic radiation emitted by these optoelectronic devices can comprise a peak wavelength within any range of wavelengths, including visible light, ultraviolet radiation, deep ultraviolet radiation, infrared light, and/or the like. For example, these optoelectronic devices can emit radiation having a dominant wavelength within the ultraviolet range of wavelengths. As an illustration, the dominant wavelength can be within a range of wavelengths of approximately 210 nanometers (nm) to approximately 350 nm.

Any of the various layers that form the optoelectronic semiconductor devices with ferromagnetic domains of the various embodiments can be considered to be transparent to radiation of a particular wavelength when the layer allows an amount of the radiation radiated at a normal incidence to an interface of the layer to pass there through. For example, a layer can be configured to be transparent to a range of radiation wavelengths corresponding to a peak emission wavelength for light, such as ultraviolet light or deep ultraviolet light, emitted by the light generating structure (e.g., peak emission wavelength+/−five nanometers). As used herein, a layer is transparent to radiation if it allows more than approximately five percent of the radiation to pass therethrough, while a layer can also be considered to be transparent to radiation if it allows more than approximately ten percent of the radiation to pass there through. Defining a layer to be transparent to radiation in this manner is intended to cover layers that are considered transparent and semi-transparent.

A layer of these optoelectronic semiconductor devices with ferromagnetic domains can be considered to be reflective when the layer reflects at least a portion of the relevant electromagnetic radiation (e.g., light having wavelengths close to the peak emission of the light generating structure). As used herein, a layer is partially reflective to radiation if it can reflect at least approximately five percent of the radiation, while a layer can also be considered to be partially reflective if it reflects at least thirty percent for radiation of the particular wavelength radiated normally to the surface of the layer. A layer can be considered highly reflective to radiation if it reflects at least seventy percent for radiation of the particular wavelength radiated normally to the surface of the layer.

The description that follows may use other terminology herein for the purpose of describing particular embodiments only and is not intended to be limiting of the disclosure. For example, unless otherwise noted, the term “set” means one or more (i.e., at least one) and the phrase “any solution” means any now known or later developed solution. The singular forms “a,” “an,” and “the” are intended to include the plural forms as well, unless the context clearly indicates otherwise. It will be further understood that the terms “comprises”, “comprising”, “includes”, “including”, “has”, “have”, and “having” when used in this specification, specify the presence of stated features, integers, steps, operations, elements, and/or components, but do not preclude the presence or addition of one or more other features, integers, steps, operations, elements, components, and/or groups thereof.

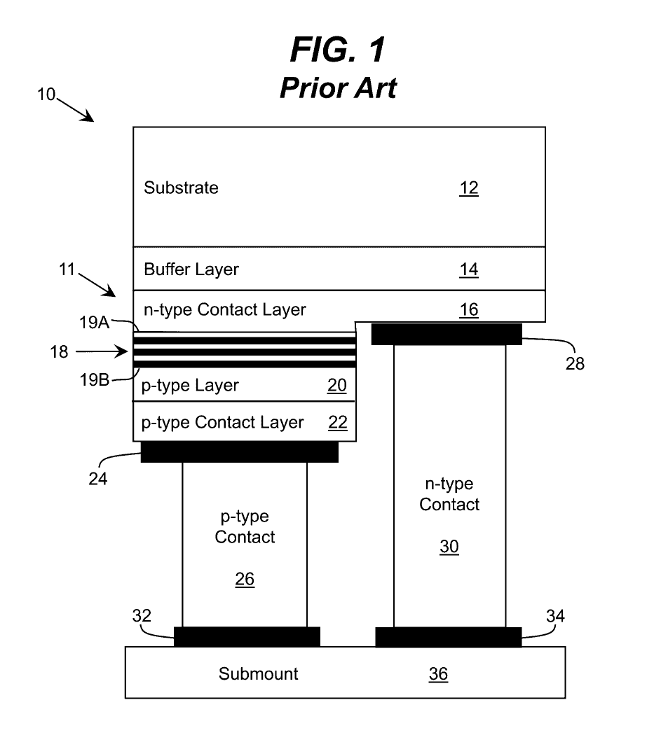

Turning to the drawings, FIG. 1 shows a schematic structure of an illustrative optoelectronic semiconductor device 10 according to the prior art. The optoelectronic semiconductor device 10 can be configured to operate as an emitting device (e.g., a LED) flip chip mounted to a substrate. One example of an LED flip chip can include a conventional or super luminescent LED. Alternatively, the optoelectronic semiconductor device 10 can be configured to operate as any of the aforementioned optoelectronic devices and/or any type of group III nitride-based device.

When the optoelectronic semiconductor device 10 is operated as an emitting device, application of a bias comparable to the band gap results in the emission of electromagnetic radiation from an active region 18 of the device 10. The electromagnetic radiation emitted by the optoelectronic semiconductor device 10 when operating as an emitting device can comprise a peak wavelength within any range of wavelengths, including visible light, ultraviolet radiation, deep ultraviolet radiation, infrared light, and/or the like. The optoelectronic semiconductor device 10 can be configured to emit radiation having a dominant wavelength within the ultraviolet range of wavelengths. More specifically, the dominant wavelength can be within a range of wavelengths between approximately 210 and approximately 350 nanometers.

As shown in FIG. 1, the optoelectronic semiconductor device 10 can include a heterostructure 11 comprising a substrate 12, a buffer layer 14 adjacent to the substrate 12, an n-type contact layer 16 (e.g., an n-type cladding layer, an electron supply layer) adjacent to the buffer layer 14, and the active region 18 having an n-type side 19A adjacent to the n-type contact layer 16. Furthermore, the heterostructure 11 of the optoelectronic semiconductor device 10 can include a p-type layer 20 (e.g., an electron blocking layer) adjacent to a p-type side 19B of the active region 18, and a p-type contact layer 22 (e.g., a hole supply layer, a p-type cladding layer) adjacent to the p-type layer 20.

The optoelectronic semiconductor device 10 can be a group III-V materials based device, in which some or all of the various layers are formed of elements selected from the group III-V materials system. In a more particular illustrative embodiment, the various layers of the optoelectronic semiconductor device 10 can be formed of group III nitride based materials. Group III nitride materials comprise one or more group III elements (e.g., boron (B), aluminum (Al), gallium (Ga), and indium (In)) and nitrogen (N), such that B_{W}Al_{X}Ga_{Y}In_{Z}N, where 0≦W, X, Y, Z≦1, and W+X+Y+Z=1. Illustrative group III nitride materials can include binary, ternary and quaternary alloys such as, AlN, GaN, InN, BN, AlGaN, AlInN, AlBN, AlGaInN, AlGaBN, AlInBN, and AlGaInBN with any molar fraction of group III elements.

An illustrative embodiment of a group III nitride based optoelectronic semiconductor device 10 can include an active region 18 (e.g., a series of alternating quantum wells and barriers) composed of In_{y}AlₓGa_{1-x-y}N, Ga_{z}In_{y}AlₓB_{1-x-y-z}N, an AlₓGa₁₋ₓN semiconductor alloy, or the like. Similarly, both the n-type contact layer 16 and the p-type layer 20 can be composed of an In_{y}AlₓGa_{1-x-y}N alloy, a Ga_{z}In_{y}AlₓB_{1-x-y-z}N alloy, or the like. The molar fractions given by x, y, and z can vary between the various layers 16, 18, and 20. The substrate 12 can be sapphire, silicon carbide (SiC), silicon (Si), GaN, AlGaN, AlON, LiGaO₂, or another suitable material, and the buffer layer 14 can be composed of AlN, an AlGaN/AlN superlattice, and/or the like.

As shown with respect to the optoelectronic semiconductor device 10, a p-type metal 24 can be attached to the p-type contact layer 22 and a p-type contact 26 can be attached to the p-type metal 24. Similarly, an n-type metal 28 can be attached to the n-type contact layer 16 and an n-type contact 30 can be attached to the n-type metal 28. The p-type metal 24 and the n-type metal 28 can form p-type and n-type ohmic contacts, respectively, to the corresponding layers 22 and 16, respectively. It is understood that a contact formed between two layers is considered “ohmic” or “conducting” when an overall resistance of the contact is no larger than the larger of the following two resistances: a contact resistance such that a voltage drop at the contact-semiconductor junction is no larger than two volts; and a contact resistance at least five times smaller than a resistance of a largest resistive element or layer of a device including the contact.

The p-type metal 24 and/or the n-type metal 28 can comprise several conductive and reflective metal layers, while the n-type contact 30 and/or the p-type contact 26 can comprise highly conductive metal. The p-type contact layer 22 and/or the p-type contact 26 can be transparent (e.g., semi-transparent or transparent) to the electromagnetic radiation generated by the active region 18. For example, the p-type contact layer 22 and/or the p-type contact 26 can comprise a short period superlattice lattice structure, such as a transparent magnesium (Mg)-doped AlGaN/AlGaN short period superlattice structure (SPSL). Furthermore, the p-type contact 26 and/or the n-type contact 30 can be reflective of the electromagnetic radiation generated by the active region 18. The n-type contact layer 16 and/or the n-type contact 30 can also be formed of a short period superlattice, such as an AlGaN SPSL, which is transparent to the electromagnetic radiation generated by the active region 18.

FIG. 1 further shows that the optoelectronic semiconductor device 10 can be mounted to a submount 36 via the contacts 26 and 30. In this case, the substrate 12 is located on the top of the optoelectronic semiconductor device 10. To this extent, the p-type contact 26 and the n-type contact 30 can both be attached to a submount 36 via contact pads 32 and 34, respectively. The submount 36 can be formed of aluminum nitride (AlN), silicon carbide (SiC), and/or the like.

Any of the various layers of the optoelectronic semiconductor device 10 can comprise a substantially uniform composition or a graded composition. For example, a layer can comprise a graded composition at a heterointerface with another layer. The p-type layer 20 can also comprise a p-type blocking layer having a graded composition. The graded composition(s) can be included to, for example, reduce stress, improve carrier injection, and/or the like. Similarly, a layer can comprise a superlattice including a plurality of periods, which can be configured to reduce stress, and/or the like. In this case, the composition and/or width of each period can vary periodically or aperiodically from period to period.

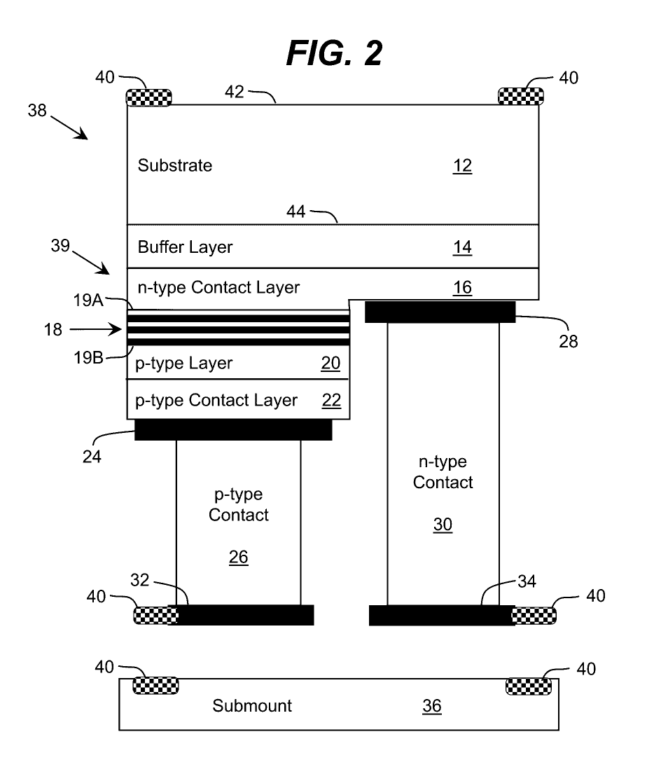

FIG. 2 shows a schematic of an optoelectronic semiconductor device 38 similar to the device 10 depicted in FIG. 1, except that the optoelectronic semiconductor device 38 of FIG. 2 includes ferromagnetic domains 40. As used herein, a ferromagnetic domain is a region having a high susceptibility to magnetization, the strength of which depends on that of the applied magnetizing field, and that may persist after removal of the applied field. FIG. 2 shows that the ferromagnetic domains 40 can be located on various regions of the optoelectronic semiconductor device 38. Ferromagnetic domains 40 located about the optoelectronic semiconductor device 38 can include domains that are located on an exterior surface of the optoelectronic semiconductor device 38 and ferromagnetic domains 40 that are located within a semiconductor structure 39 that forms a part of the device 38.

As shown in FIG. 2, the semiconductor structure 39 can include the substrate 12, the buffer layer 14 formed over the substrate, and the n-type contact layer 16 formed over the buffer layer and the substrate 12. In addition, the semiconductor structure 39 can include the active layer 18 formed between the n-contact layer 16 and the p-type layer 20 and the p-type contact layer 22. The p-type contact 26 and the n-type contact 30 can contact the semiconductor structure 39 via the p-type metal 24 and the n-type metal 28, respectively. In this manner, the semiconductor structure 39 of the optoelectronic semiconductor device 38 can mount to the submount 36 via the p-type contact 26 and the n-type contact 30 and contact pads 32 and 34, respectively.

FIG. 2 illustrates various locations in which the ferromagnetic domains can be located with respect to the optoelectronic semiconductor device 38 and the semiconductor structure 39. In one embodiment, at least one ferromagnetic domain 40 can be formed on an outer surface 42 of the substrate 12, opposing an inner surface 44 of the substrate having the buffer layer 14 and the n-type contact layer 15 formed there over. In another embodiment, at least one ferromagnetic domain 40 can be formed with at least one of the pair of contact pads 32 and 34, and the submount 36. For example, FIG. 2 shows that each contact pad 32 and 34 includes a ferromagnetic domain 40 and the submount 36 includes a pair of ferromagnetic domains 40, with each in alignment with one of the ferromagnetic domains of the contact pads 32, 34. It is understood that the location of the ferromagnetic domains 40 on and/or within the optoelectronic semiconductor device 38 and the semiconductor structure 39 as depicted in FIG. 2 is only representative of various options, and that others are within the scope of the various embodiments of the present invention. For example, the buffer layer 14, the n-type contact layer 16, the p-type layer 20 and the p-type contact layer 22 can have ferromagnetic domains 40 attached thereto or embedded therein.

The ferromagnetic domains 40 can include a variety of different ferromagnetic materials. In one embodiment, the ferromagnetic domains 40 can include an iron-based alloy. Other ferromagnetic material that is suitable for use in the ferromagnetic domains 40 can include, but is not limited to, iron, a neodymium magnet, and similar ferromagnetic materials such as cobalt, metallic alloys and oxides (e.g., magnetite), and/or the like. In one embodiment, at least one ferromagnetic domain 40 can include a ferromagnetic material with a relative magnetic permeability of at least 20% of the iron. A benefit of having a ferromagnetic domain 40 with a ferromagnetic material with a relative magnetic permeability of at least 20% of the iron includes an ability to maintain sufficient magnetic forces for manipulation of the epitaxially grown structures. In another embodiment, at least one of the ferromagnetic domains 40 can be magnetized to facilitate a bonding with other magnetized surfaces that can include, but are not limited to, the ferromagnetic domains, electromagnets, and the like.

The ferromagnetic domains 40 can be formed about the optoelectronic semiconductor device 38, including within the semiconductor structure 39, in one of a multitude of approaches. For example, the ferromagnetic domains 40 can be incorporated by evaporating a ferromagnetic material over a surface of any layer of the semiconductor structure 39; wherein the layer can be a semiconductor layer, a substrate, or a metallic contact layer. In other embodiments, the ferromagnetic material can be sputtered, soldered, or glued to a surface of a layer. In some cases, the ferromagnetic materials can be deposited within the semiconductor structure 39 and/or incorporated within the substrate 12. In an embodiment, the substrate 12 can be patterned to have ferromagnetic elements of ferromagnetic material. In this manner, a patterned substrate can contain ferromagnetic elements of the ferromagnetic material deposited in the valleys of patterned sites. This can be further enclosed by an appropriate masking material such as SiO₂, which can prevent a chemical interaction of ferromagnetic elements during an epitaxial growth process of additional layers and/or structures. Similarly, the ferromagnetic material can be deposited in the valleys of patterned semiconductor layers, followed by appropriate masking.

A magnetic force generated from a magnetic field can be used to process optoelectronic semiconductor devices with ferromagnetic domains such as the device 38 depicted in FIG. 2, as well other optoelectronic semiconductor devices that utilize the ferromagnetic domains. This processing can include moving these optoelectronic semiconductor devices with a magnetic force generated from a magnet such as an electromagnet, forming these devices with additional semiconductor structures, attaching electrodes, and assembling the optoelectronic semiconductor devices with ferromagnetic domains into systems of optoelectronic devices. The processing of the optoelectronic semiconductor devices with ferromagnetic domains can be implemented by an automated system, such as a device and/or circuit fabrication system, that can include robotic arms with electromagnets, and/or the like. This processing can be performed on a single optoelectronic semiconductor device with ferromagnetic devices or a set of these devices.

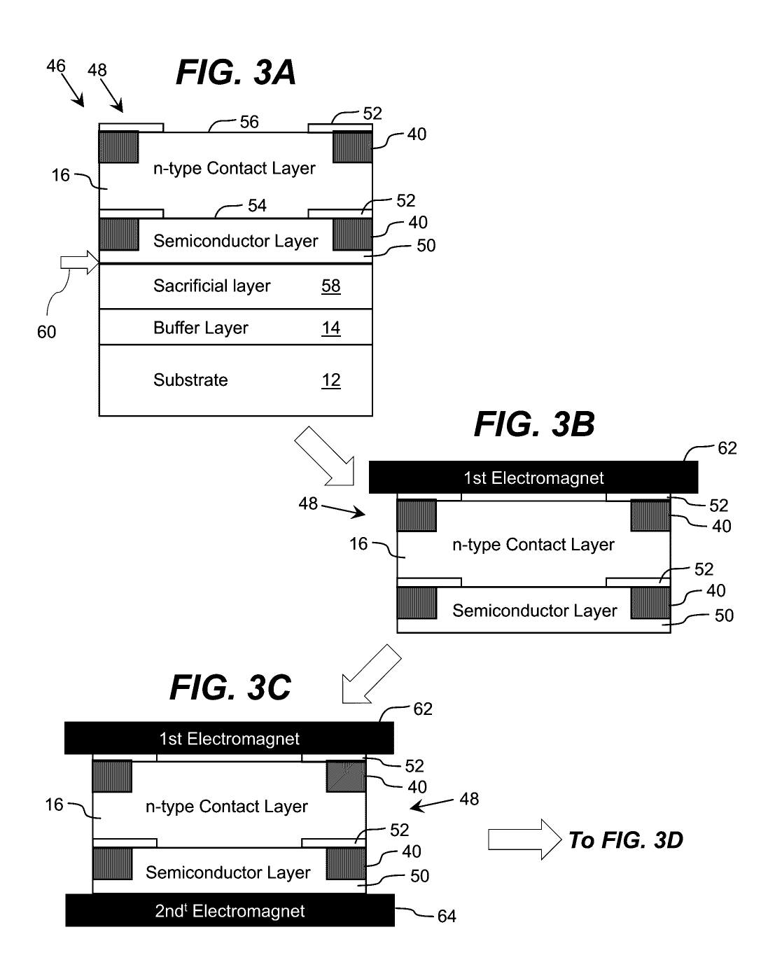

FIGS. 3A-3E show an illustrative method for processing an optoelectronic semiconductor device 46 having ferromagnetic domains 40 according to an embodiment of the present invention. The optoelectronic semiconductor device 46 can include a semiconductor structure 48 which is shown in FIG. 3A as having an n-type contact layer 16 formed over a semiconductor layer 50, with ferromagnetic domains 40 located about these layers and a masking layer 52, such as SiO₂, formed on an inner surface 54 and an outer surface 56 of the n-type contact layer 16. These elements of the semiconductor structure 48 can be formed over a sacrificial layer 58, a buffer layer 14 and a substrate 12. It is understood that in this part of the method depicted in FIGS. 3A-3E, the optoelectronic semiconductor device 46 including the semiconductor structure 48 can be part of an epitaxial growth process in which these elements can be formed in an epitaxial growth chamber or can already be grown and obtained for this part of the processing method.

Any of the aforementioned materials noted for the n-type contact layer 16, the buffer layer 14 and the substrate 12 are also suitable for use with the optoelectronic semiconductor device 46 including the semiconductor structure 48. The supporting semiconductor layer 50, which can serve as a layer including one or more ferromagnetic domains that can be manipulated by a magnet, also can include any of the previously mentioned group III nitride materials.

The sacrificial layer 58 can include a material that is capable of being grown over the semiconductor structure 48 with the buffer layer 14 and the substrate layer 12 coupled thereto. In one embodiment, the sacrificial layer 58 can be suitable for use in lift-off techniques where the semiconductor structure 48 is removed from a lattice mismatched substrate 12, the buffer layer 14 and the sacrificial layer 58. In one embodiment, the sacrificial layer 58 can include a material having a high absorption to laser radiation at a target wavelength. In one embodiment, the sacrificial layer 58 can include a group III nitride semiconductor layer with a bandgap value that is lower than the bandgap value of any layer in the semiconductor structure 48. For example, the sacrificial layer 58 can include GaN. In another embodiment, the sacrificial layer 58 can include columnar structures comprising group III nitride semiconductors epitaxially grown over a masked region that has holes or openings for growing sacrificial layer material. In another embodiment, the sacrificial layer 58 can include a semiconductor layer containing openings, vacancies, or a set of disjoint columnar structures. In yet another embodiment, the sacrificial layer 58 can include combinations of any of the aforementioned sacrificial layers. Also, the sacrificial layer 58 can include tensile and compressive layers. U.S. Provisional Application 62/187,707, entitled “A method of releasing group III nitride semiconductor heterostructure,” which was filed on 1 Jul. 2015 provides further details of a sacrificial layer that is suitable for use with the semiconductor structure 48 and is incorporated herein by reference.

In one embodiment, the semiconductor structure 48 can be separated from the substrate 12, the buffer layer 14 and the sacrificial layer 58 by irradiating the semiconductor layers that can form the semiconductor structure from the substrate side to decompose the sacrificial layer 58, thus separating the semiconductor structure 48 from the substrate 12 and the buffer layer 14. This decomposing lift-off operation is depicted in FIG. 3A by the arrow 60 directed towards the sacrificial layer 58. A laser lift-off using laser radiation is one example of a lift-off technique that can be used to lift semiconductor layers such as a semiconductor structure from a substrate. For example, the semiconductor structure 48 could be radiated from the substrate side with a high intensity laser (in a laser ablation) that is largely absorbed by the sacrificial layer 58, resulting in decomposition of the sacrificial layer 58. A laser lift-off is a well-known technique in the art that is used to separate semiconductor layers from a substrate 12, which can result in improved characteristics of a subsequently fabricated optoelectronic device. U.S. Provisional Application 62/187,707 provides further details of several laser-lift off techniques that can be used to irradiate group III nitride semiconductor layers from the substrate side to decompose a sacrificial layer.

FIG. 3B shows the semiconductor structure 48 after a lift-off operation 60 has been performed through, for example, an application of a laser emission at a specified wavelength that was absorbed by the sacrificial layer 58, causing it to decompose and separate from the substrate 12 and the buffer layer 14. FIG. 3B further shows a part of the processing method in which a first electromagnet 62 can be used to move the semiconductor structure 48 away from the substrate 12 and the buffer layer 14. In this part of the method, the first electromagnet 62 can attach to a first side of the semiconductor structure 48, which can be the n-type contact layer 16. The first magnet can be utilized to lift-off the semiconductor structure 48 from the substrate 12, which results in a thin film semiconductor structure. In one embodiment, the first electromagnet 62 can be part of an automated robotic system that can include a robotic arm with the electromagnet affixed thereto that is programmed to attach to the semiconductor structure 48 and facilitate the lift-off operation from the substrate 12. The use of a robotic arm is illustrative of one possible modality that can be used to lift-off the semiconductor structure 48 and is not meant to limit the various embodiments of processing optoelectronic semiconductor devices with ferromagnetic domains. For example, other systems that can be used to process optoelectronic semiconductor devices with ferromagnetic domains can include manual tools for lifting layers attached to a magnet.

After the thin film semiconductor structure 48 has been lifted off and away from the substrate 12, the next part of the method depicted in FIGS. 3A-3E can include carrying the structure to another site for further processing. In one embodiment, as depicted in FIG. 3C, a second electromagnet 64 can be applied to a second side of the semiconductor structure 48 opposite the first side with the first electromagnet 62 affixed thereto. For example, the second electromagnet 64 can be applied to a surface of the semiconductor layer 50. It is understood that the specific layers to which each of the electromagnets adhere is only illustrative of one possibility and is not meant to limit the various embodiments described herein.

In order for the second electromagnet 64 to move the semiconductor structure 48 to another location for further processing, the first electromagnet 62 can be detached from the structure as depicted in FIG. 3D. The first electromagnet 62 can be removed from the n-type contact layer 16 of the semiconductor structure 48 using one of a number of different approaches. In one embodiment, the first electromagnet 62 can be removed from the n-type contact layer 16 of the semiconductor structure 48 by operating the electromagnet 62 to have an electromagnetic force that repulses from the second electromagnet 64. In order to easily detach the first electromagnet 62 from the n-type contact layer 16 of the semiconductor structure 48 in this embodiment, the force of magnetic attraction between the electromagnet 62 and the ferromagnetic domains 40 in the n-type contact layer can be different than the force of attraction between the second electromagnet 64 and the ferromagnetic domains 40 in the semiconductor layer 50. For instance, the ferromagnetic domains 40 in the n-type contact layer 16 and the semiconductor layer 16 can be magnetized with different ferromagnetic elements for the optimal control of the lift-off process, including the separation of the electromagnets from the semiconductor structure. In addition, the masking layers on both sides 54, 46 of the n-type contact layer 16 can have different thicknesses. Applying these masking layers 52 to the ferromagnetic domains 40 will cause the domains to have different attractive forces.

Another embodiment of removing the first electromagnet 62 from the n-type contact layer 16 of the semiconductor structure 48 can include detaching the electromagnet prior to activation of the second electromagnet 64. For example, the second electromagnet 64 can be applied to the semiconductor layer 50 while the first electromagnet 62 is activated and adhering to the n-contact layer 16. However, the second electromagnet 64 would not yet be activated. The first electromagnet 62 can then be deactivated to remove the magnetic force from being applied to the n-type contact layer 16. In one embodiment, the second electromagnet 64 can include a surface that can adhere to the semiconductor layer 50 of the semiconductor structure without the presence of a magnetic field. Examples of such a material that can be applied to the electromagnet 64 can include, but are not limited to, various adhesives.

The first electromagnet 62 can also be removed from the n-type contact layer 16 of the semiconductor structure 48 after the second electromagnet 64 has been applied to the semiconductor layer 50 and activated. For example, in one embodiment, the second electromagnet 64 can be activated in response to a positive pole of the electromagnet 64 being adjacent to a positive pole of the first electromagnet 62 and a negative pole of the second electromagnet 64 being adjacent to a negative pole of the first electromagnet 62. The first electromagnet 62 can then be detached after the activation of the second electromagnet 64. For example, in one embodiment, the first electromagnet 62 can be removed from the first side (e.g., the n-type contact layer 16) of the semiconductor structure 48 by reversing a direction of current and reducing an amount of the current applied to the first electromagnet 62. In this manner, the first electromagnet 62 can then detach from both the semiconductor structure 48 and the second electromagnet 64.

After the first electromagnet 62 has been removed, the second electromagnet 64 can be utilized to move the semiconductor structure 64 to the next location for subsequent processing. Once at that location, the second electromagnet 64 can be detached from the semiconductor layer 50 side of the semiconductor structure 48. In one embodiment, the second electromagnet 64 can be detached by removing the magnetic force applied to the semiconductor layer 50.

The first electromagnet 62 and the second electromagnet 64 can each have different ferromagnetic domains in order to facilitate their attaching and detaching from the semiconductor structure 48. In one embodiment, the first electromagnet 62 can include a set of ferromagnetic domains with a force of attraction that are different from the force of attraction of the ferromagnetic domains of the second electromagnet 64.

Although electromagnets are described in use with this embodiment, it is understood that other type of magnets could be used. For example, permanent magnets can be used in the lift-off and moving operations of the semiconductor structure 48. It is understood that due to the difference in operation of a permanent magnet in comparison to an electromagnet, changes to the system for carrying out this method would likely be necessary. For example, another modality such as additional robotic arm would likely be necessary to remove semiconductor structure 48 away from the permanent magnet.

Two electromagnets are described in carrying out this processing method, however, it is also understood that more or less electromagnets can be deployed. For example, a single electromagnet can be used to facilitate the lift-off as well as the carrying or moving operation. It is understood that the use of a single electromagnet would likely necessitate some changes in the aforementioned process, however, those changes are well within the purview of those skilled in the art.

Also, it is understood that other modalities besides magnets can be used to effectuate the lift-off and carrying operations. In one embodiment, a suction or vacuum holder can be substituted for one of the electromagnets. For example, the second electromagnet 64 can be substituted by a suction holder, and the step of epitaxial growth over template which is described below with respect to FIG. 3E can be accomplished by removing the first electromagnet 62.

After the second electromagnet 64 has been removed, the semiconductor structure 48 can be used as a template for subsequent epitaxial growth of additional semiconductor layers so that these extra layers can be grown without the use of a mismatched substrate. For example, in this embodiment, the second electromagnet 64 can carry the semiconductor structure 48 to an epitaxial growth chamber. Once the second electromagnet 64 has been removed from the semiconductor structure, the epitaxial chamber can be operated to grow or form other elements in order to assemble the optoelectronic semiconductor device 62. For example, FIG. 3E shows the semiconductor structure 48 with a mesa structure 65 that can include an additional layer of the n-type contact layer 16, an active layer 18 formed over the n-type contact layer, and a p-type contact layer 20. The semiconductor structure with this mesa structure 65 can form the optoelectronic semiconductor device 46. It is understood that the optoelectronic semiconductor device 46 with ferromagnetic domains 40 is only illustrative of one optoelectronic device that can be assembled with ferromagnetic domains, and that can be processed according to the method depicted in FIGS. 3A-3E, and is not meant to limit the various embodiments of the present invention described herein. For example, the optoelectronic semiconductor device 46 can have a pair of electrodes formed over the p-type contact layer 20 and the semiconductor layer 50. In one embodiment, an n-type electrode can be formed over the semiconductor layer 50, while a p-type electrode can be formed over the p-type contact layer 20, to create a vertical optoelectronic semiconductor device.

Although the description for FIG. 3E is with respect to the option of using the semiconductor structure 48 as a template for epitaxial growth of additional elements for the optoelectronic semiconductor device 46, it is understood that the entire or complete device can be epitaxially grown prior to the lift-off operation. Therefore, the various embodiments described herein with respect to the processing method depicted in FIGS. 3A-3E is not meant to be limited to lift-off of semiconductor layers for template growth.

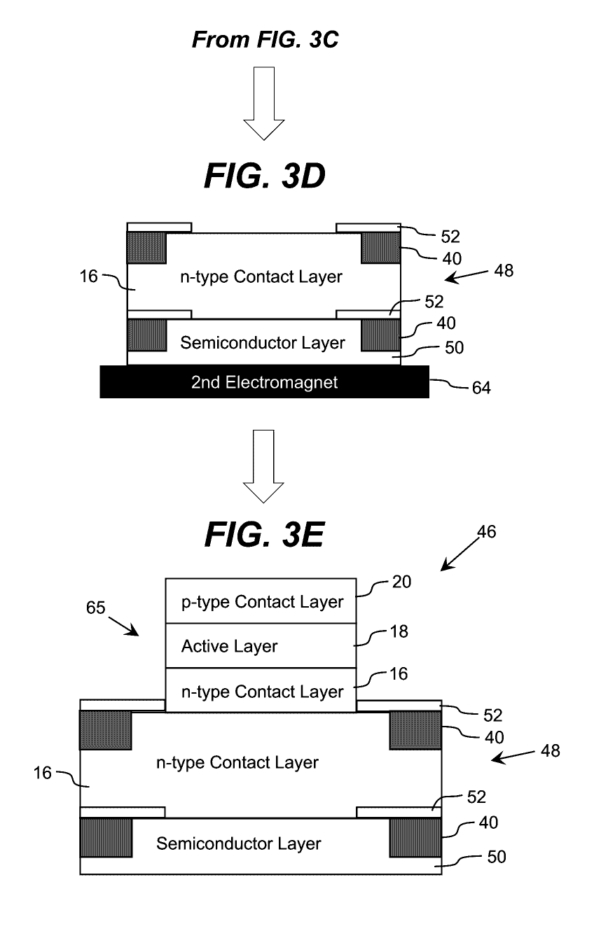

FIGS. 4A-4C shows schematics of another optoelectronic semiconductor device 66 that can have a ferromagnetic domain 70 according to an embodiment of the present invention. In particular, FIGS. 4A-4B show a top view and a perspective view, respectively, of the optoelectronic semiconductor device 66 with a mesa structure 68 and a ferromagnetic domain 70 located on an exterior surface of the device, while FIG. 4C shows a set of optoelectronic semiconductor devices 66 depicted in FIGS. 4A-4B. FIGS. 4A-4B also show that the optoelectronic semiconductor device 66 can include a substrate 72 and a contact pad 74 for a metallic contact (e.g., an n-type metallic contact). The aforementioned materials for a substrate, contact pad, metallic contact and ferromagnetic domains are also suitable for use with the optoelectronic semiconductor device 66.

Although not illustrated in FIGS. 4A-4C, the optoelectronic semiconductor device 66 can include a semiconductor structure that forms a part of the mesa structure 68 or constitutes the mesa structure. For example, the semiconductor structure can include an n-type contact layer, an active layer formed over the n-type contact layer, and a p-type contact layer formed over the active layer. It is understood, that the semiconductor structure could include additional elements or it could take the form of an entirely different structure. Furthermore, it is understood, that some of the layers that form the semiconductor structure can have ferromagnetic domains embedded therein or attached thereto. Also, it is understood that the optoelectronic semiconductor device 66 can take the form of any of the above-noted optoelectronic devices such as, for example, an LED.

Since the ferromagnetic domains 70 are located on an exterior surface of the optoelectronic semiconductor device 66 it is possible to place the domains on the surface after the fabrication of the device. For example, in one embodiment, as shown in FIG. 4A, the ferromagnetic domain 70 can be placed over the substrate 72. In another embodiment, as shown in FIG. 4B, the ferromagnetic domain 70 can be placed over the mesa structure 68. In still another embodiment, the ferromagnetic domain 70 can be placed over the contact pad 74. It is understood, that more than one ferromagnetic domain can be placed over the exterior surface of the optoelectronic semiconductor structure 66. For example, a ferromagnetic domain 70 can be placed over a combination of locations including, but not limited to, the substrate 72, the mesa structure 68 and the contact pad 74.

The ferromagnetic domain 70 placed over the exterior surface of the optoelectronic semiconductor device 66 can be implemented through a variety of approaches. For example, the ferromagnetic domain 70 can be deposited using vapor deposition. In an embodiment, the ferromagnetic domain 70 can be deposited in a previously etched domain. In an alternative embodiment, the ferromagnetic domain 70 can comprise a thin ferromagnetic adhesive film that can be placed on a desired location of a surface of the optoelectronic semiconductor device 66.

In one embodiment, as shown in FIG. 4C, a set of the optoelectronic semiconductor devices 66 can be used in a flip-chip configuration. As shown in FIG. 4C, the optoelectronic semiconductor devices 66 can be positioned over a pair of electrodes 76 and 78 in a flip chip configuration using a magnetic strip 80 placed in parallel with the pair of spaced electrodes for guiding and assembly of the set of devices over the electrodes 76 and 78.

A method for carrying out an assembly of a set of optoelectronic semiconductor devices 66 in a flip-chip configuration can begin by obtaining a set of devices, each having a semiconductor structure including a substrate 72, an n-type contact layer formed over the substrate, an active layer formed over the n-type contact layer, and a p-type contact layer formed over the active layer, and at least one ferromagnetic domain 70 located about the semiconductor structure. The set of optoelectronic semiconductor devices can be placed in proximity to a magnetic force. For example, an electromagnet (e.g., including the magnetic strip 80) can be placed over one or more of the optoelectronic semiconductor devices 66 such that the magnetic force causes an attraction of the devices to the electromagnet. The electromagnet can then guide the set of optoelectronic semiconductor devices 66 from a first location to a second location over the pair of spaced electrodes 76 and 78 with the magnetic force. A robotic arm or the like that utilizes the electromagnet can use the magnetic strip 80 to more precisely align the ferromagnetic domains 70 of each of the optoelectronic semiconductor devices in order to facilitate placement over the electrodes 76 and 78. The robotic arm can then release the optoelectronic semiconductor devices onto the pair of spaced electrodes 76, 78 in response to an alignment of the ferromagnetic domains 70 to the magnetic strip 80 (e.g., deactivating or turning off the electromagnet to release the magnetic force).

It is understood that this method is illustrative of one approach of processing a set of the optoelectronic semiconductor devices 66 and that other possibilities exist. For example, the method could include more or less steps than that described. Also, it is understood that some of these steps can be performed in a different order than that described. Furthermore, it is understood that more complex devices or systems can be formed from the set of the optoelectronic semiconductor devices 66. For example, additional optoelectronic semiconductor devices 66 can be placed over devices that have already been positioned over the electrodes 76, 78. In this scenario, the same procedure used to position the set of optoelectronic semiconductor devices 66 over the electrodes 76, 78 can be repeated to place another set over those devices on the electrodes.

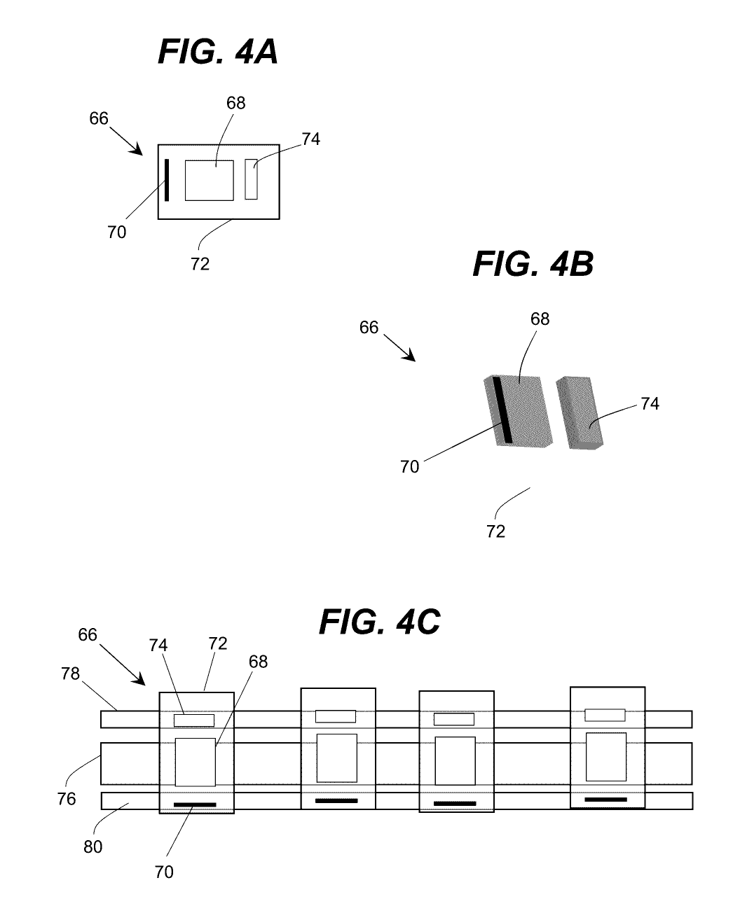

FIG. 5 shows a schematic of an assembly of an optoelectronic device 82 formed from two optoelectronic semiconductor devices 84 and 86 (device 1 and device 2) each having ferromagnetic domains 40 according to an embodiment of the present invention. In this embodiment, the ferromagnetic domains 40 of the optoelectronic semiconductor devices 84 and 86 are coupled to each other. That is, the ferromagnetic domains 40 of the optoelectronic semiconductor device 84 are attracted to the ferromagnetic domains 40 of the optoelectronic semiconductor device 86 to form a physical, mechanical connection between the devices when their domains are placed in close proximity to each other. In one embodiment, the ferromagnetic domains 40 can include depressions that are complementary to the depressions of other domains in order to attain a more secure connection between the domains of the coupled devices.

The optoelectronic semiconductor devices 84 and 86 can take on the form of any of the aforementioned optoelectronic devices. In addition, these devices can include semiconductor structures such as any of the previously described structures, however, it is understood that there is a multiple of possible of other structures that could be deployed as the optoelectronic semiconductor devices 84 and 86. In one embodiment, the optoelectronic semiconductor devices 84 and 86 can each have a p-type contact and an n-type contact. In one embodiment, each contact can be formed on opposing sides of the semiconductor structure, with one of the contacts formed on a side containing the ferromagnetic domains 40. For example, as shown in FIG. 5, the optoelectronic semiconductor device 84 can have a p-type contact 88 and an n-type contact 90, while the optoelectronic semiconductor device 86 can have a p-type contact 92 and an n-type contact 94. In this example, the p-type contact 88 of the optoelectronic semiconductor devices 84 is placed between the ferromagnetic domains 40, while the p-type contact 92 of the optoelectronic semiconductor devices 86 is placed between the ferromagnetic domains 40.

With this configuration, a contact can be made between the p-type contact 88 of the optoelectronic semiconductor device 84 and the p-contact 92 of the optoelectronic semiconductor device 88 upon the magnetic coupling of each of the devices. In one embodiment, solder, glue, an adhesive, or the like can be used to facilitate the contact between the p-type contact 88 and the p-type contact 92. In another embodiment, the p-type contact 88 and the p-type contact 92 can be designed with a larger contact area in order to attain a more secure contact between these elements. It is understood that the configuration of the contacts and the ferromagnetic domains depicted in FIG. 5 is only illustrative of one implementation and that those skilled in the art will appreciate that other arrangements exist. For example, the n-type contacts 90 and 94 can be positioned between the ferromagnetic domains 40 such that there is contact there between upon a coupling of the ferromagnetic domains 40 of each of the devices.

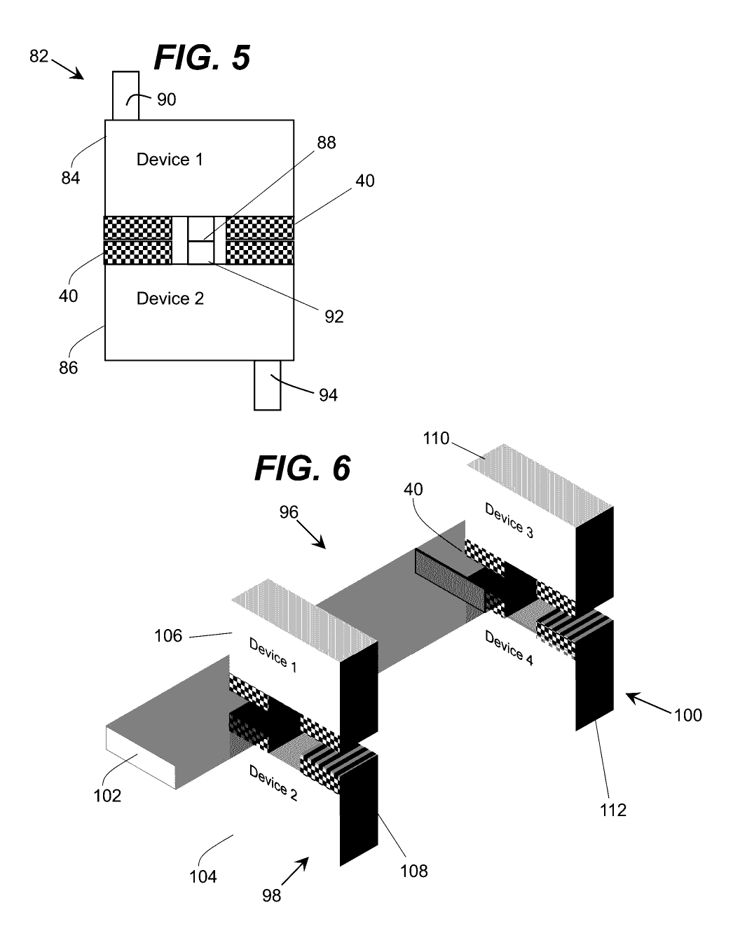

In one embodiment, the ferromagnetic domains 40 of each of the coupled optoelectronic semiconductor devices can be electrically conductive by being coupled to a pair of electrodes. For example, FIG. 6 shows a schematic of an assembly of a system 96 of optoelectronic devices 98 and 100 coupled to a pair of electrodes 102 and 104 according to an embodiment of the present invention. As shown in FIG. 6, the optoelectronic device 98 can include devices 106 and 108, while the optoelectronic device 100 can include devices 110 and 112. Each of the devices that form the optoelectronic devices 98 and 100 can have ferromagnetic domains 40 attached thereto. In one embodiment, as shown in FIG. 6, the electrode 102 can be spaced apart from the second electrode 104, with each electrode disposed between the ferromagnetic domains 40 each of the devices. In this manner, the magnetic domains 40 can be electrically conductive and connected to electrodes 102 and 104. In one embodiment, the ferromagnetic domain 40 of device 110 that is coupled to the electrode 102 can comprise an n-type contact, while the ferromagnetic domain 40 of device 108 that is coupled to the electrode 104 can comprise a p-type contact. Alternatively, these ferromagnetic domains can be changed to form a p-type contact and an n-type contact.

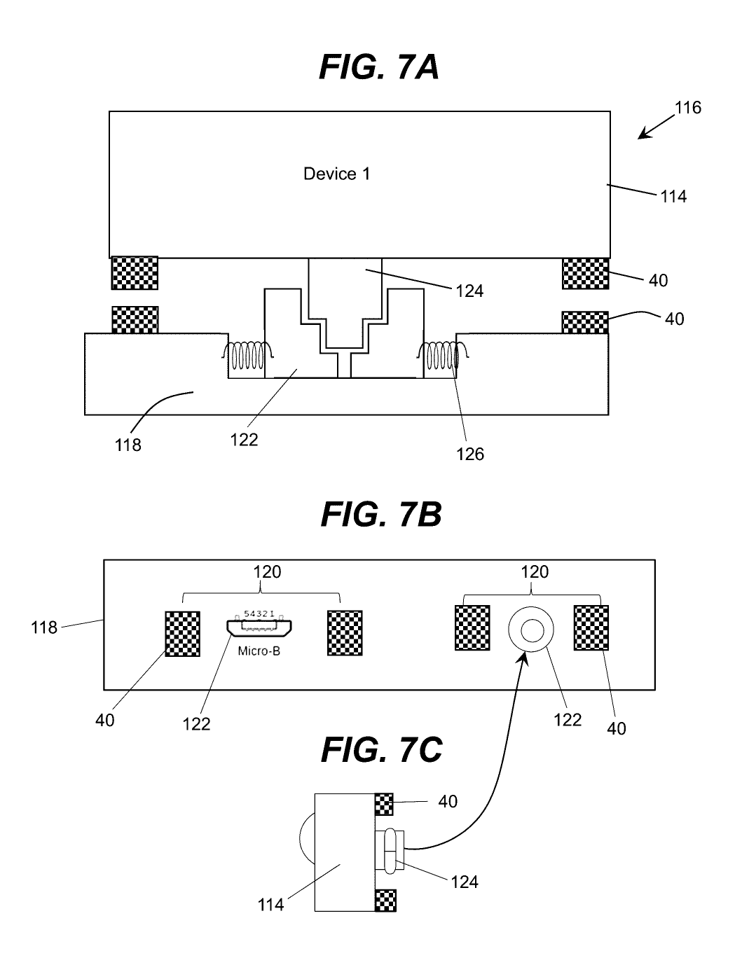

FIGS. 7A-7C show an optoelectronic semiconductor device 114 with ferromagnetic domains 40 in use in a circuit component self-assembly 116 according to an embodiment of the present invention. In particular, FIGS. 7A-7C show a schematic of the circuit component self-assembly 116 with the optoelectronic semiconductor device 114 and ferromagnetic magnetized domains 40 used as an electrical connector and a connector board 118 having input/output connectors 120 with ferromagnetic magnetized domains 40 that are complementary for coupling or interconnecting with the ferromagnetic magnetized domains 40 of the optoelectronic semiconductor device 114.

In one embodiment, as shown in FIG. 7B, each of the input/output connectors 120 can include a port 122 to connect with an electrical device (e.g., the optoelectronic semiconductor device 114) and at least one ferromagnetic magnetized domain 40 located about the port to facilitate a connection with the electrical device and its ferromagnetic domains. The ports can take the form of one of a number of well-known types of ports that facilitate various types of connections. The ports 122 can provide serial connections and/or parallel connections in order to facilitate an electrical connection with a number of different electrical devices. For example, as shown in FIG. 7B, the ports 122 of the input/output connectors 120 from the connector board 118 can include USB ports and cable ports (e.g., button ports). It is understood that the connector board can have a multitude of different ports as well a different amount of ports than what is depicted in FIG. 7B. The types of ports and the amount will depend on the type of electrical devices that are to be connected to these ports.

In one embodiment, the type of electrical device that connects to the connector board can include the optoelectronic semiconductor device 114. Although not shown in FIGS. 7A-7C, the optoelectronic semiconductor device 114 can be formed from any of the semiconductor structures described earlier, however, other types of structures are within the scope of the various embodiments of the present invention. In one embodiment, the assembly can be for a lighting device that has a connector board with ferromagnetic domains that can connect to the optoelectronic semiconductor device 114 through its ferromagnetic magnetized domains. For example, the optoelectronic semiconductor device 114 can include an LED such that one or more of the LEDs can be utilized in lighting device such as a lamp.

As shown in FIGS. 7A and 7B, the optoelectronic semiconductor device 114 can include an electrical connector 124 adapted for connection into a port 122 of one of the input/output connectors 120. In addition, the electrical connector 124 can have ferromagnetic magnetized domains 40 located about the electrical connector. In this manner, the ferromagnetic magnetized domains 40 of the electrical connector 124 can be coupled to the ferromagnetic magnetized domains 40 of the input/output connector 120 upon insertion of the electrical connector into the port 122. For example, in one embodiment, a pair of ferromagnetic magnetized domains 40 can be located on opposing sides of the electrical connector 124 and a pair ferromagnetic magnetized domains 40 can be located on opposing sides of the port 120. The insertion of the electrical connector 124 into the port 122 along with the mating of each of the respective pairs of ferromagnetic magnetized domains 40 will result in a physical, mechanical coupling of the device 114 to the connector board 118 such that the device snaps into place with the board. This pairs of ferromagnetic magnetized domains 40 also have the benefit of enabling the electrical connector 124 to be mechanically guided towards the input/output connector 120.

It is understood that other connectors can be used in addition to the ferromagnetic domains 40 to attain an even more secure coupling. For example, as shown in FIG. 7A, a spring mechanism 126 can be placed between the port 120 and the connector board 118 to further secure the connection of female and male electrical parts. Those skilled in the art will appreciate that other approaches can be utilized to further secure the connection between the optoelectronic semiconductor device 114 and the connector board 118.

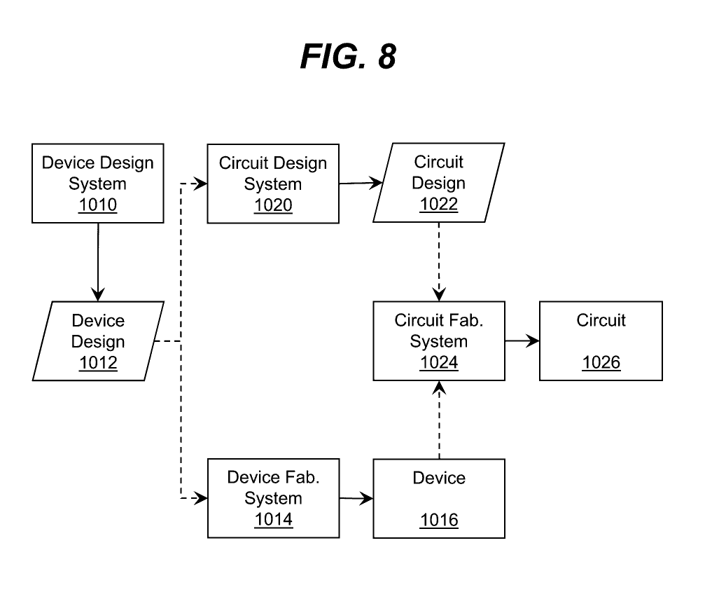

In one embodiment, the invention provides a method of designing and/or fabricating a circuit that includes one or more of the devices designed and fabricated as described herein (e.g., including one or more devices having a set of ferromagnetic domains described herein). To this extent, FIG. 8 shows an illustrative flow diagram for fabricating a circuit 1026 according to an embodiment. Initially, a user can utilize a device design system 1010 to generate a device design 1012 for a semiconductor device as described herein. The device design 1012 can comprise program code, which can be used by a device fabrication system 1014 to generate a set of physical devices 1016 according to the features defined by the device design 1012. Similarly, the device design 1012 can be provided to a circuit design system 1020 (e.g., as an available component for use in circuits), which a user can utilize to generate a circuit design 1022 (e.g., by connecting one or more inputs and outputs to various devices included in a circuit). The circuit design 1022 can comprise program code that includes a device designed as described herein. In any event, the circuit design 1022 and/or one or more physical devices 1016 can be provided to a circuit fabrication system 1024, which can generate a physical circuit 1026 according to the circuit design 1022. The physical circuit 1026 can include one or more devices 1016 designed as described herein.

In another embodiment, the invention provides a device design system 1010 for designing and/or a device fabrication system 1014 for fabricating a semiconductor device 1016 as described herein. In this case, the system 1010, 1014 can comprise a general purpose computing device, which is programmed to implement a method of designing and/or fabricating the semiconductor device 1016 as described herein. Similarly, an embodiment of the invention provides a circuit design system 1020 for designing and/or a circuit fabrication system 1024 for fabricating a circuit 1026 that includes at least one device 1016 designed and/or fabricated as described herein. In this case, the system 1020, 1024 can comprise a general purpose computing device, which is programmed to implement a method of designing and/or fabricating the circuit 1026 including at least one semiconductor device 1016 as described herein. In either case, the corresponding fabrication system 1014, 1024, can include a robotic arm and/or electromagnet, which can be utilized as part of the fabrication process as described herein.

In still another embodiment, the invention provides a computer program fixed in at least one computer-readable medium, which when executed, enables a computer system to implement a method of designing and/or fabricating a semiconductor device as described herein. For example, the computer program can enable the device design system 1010 to generate the device design 1012 as described herein. To this extent, the computer-readable medium includes program code, which implements some or all of a process described herein when executed by the computer system. It is understood that the term “computer-readable medium” comprises one or more of any type of tangible medium of expression, now known or later developed, from which a stored copy of the program code can be perceived, reproduced, or otherwise communicated by a computing device.

In another embodiment, the invention provides a method of providing a copy of program code, which implements some or all of a process described herein when executed by a computer system. In this case, a computer system can process a copy of the program code to generate and transmit, for reception at a second, distinct location, a set of data signals that has one or more of its characteristics set and/or changed in such a manner as to encode a copy of the program code in the set of data signals. Similarly, an embodiment of the invention provides a method of acquiring a copy of program code that implements some or all of a process described herein, which includes a computer system receiving the set of data signals described herein, and translating the set of data signals into a copy of the computer program fixed in at least one computer-readable medium. In either case, the set of data signals can be transmitted/received using any type of communications link.

In still another embodiment, the invention provides a method of generating a device design system 1010 for designing and/or a device fabrication system 1014 for fabricating a semiconductor device as described herein. In this case, a computer system can be obtained (e.g., created, maintained, made available, etc.) and one or more components for performing a process described herein can be obtained (e.g., created, purchased, used, modified, etc.) and deployed to the computer system. To this extent, the deployment can comprise one or more of: (1) installing program code on a computing device; (2) adding one or more computing and/or I/O devices to the computer system; (3) incorporating and/or modifying the computer system to enable it to perform a process described herein; and/or the like.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. An optoelectronic semiconductor device, comprising:
a semiconductor structure including a substrate, an n-type contact layer formed over the substrate, an active layer formed over the n-type contact layer, and a p-type contact layer formed over the active layer; and
at least one ferromagnetic domain located on the semiconductor structure.

2. The optoelectronic semiconductor device of claim 1, wherein the at least one ferromagnetic domain is formed on an outer surface of the substrate, opposing an inner surface of the substrate having the n-type contact layer formed there over.

3. The optoelectronic semiconductor device of claim 1, wherein the semiconductor structure further includes a p-type contact formed over the p-type contact layer, an n-type contact formed over the n-type contact layer, a pair of contact pads, each contact pad formed with one of the p-type contact and the n-type contact, and a submount mounted to the p-type contact and the n-type contact via the contact pads.

4. The optoelectronic semiconductor device of claim 3, wherein the at least one ferromagnetic domain is formed with at least one of the pair of contact pads and the submount.

5. The optoelectronic semiconductor device of claim 3, wherein each contact pad includes a ferromagnetic domain and the submount includes a pair of ferromagnetic domains, each in alignment with one of the ferromagnetic domains of the contact pads.

6. The optoelectronic semiconductor device of claim 1, wherein the n-type contact layer includes the at least one ferromagnetic domain.

7. The optoelectronic semiconductor device of claim 1, wherein the semiconductor structure includes a supporting semiconductor layer formed over a first surface of the n-type contact layer, opposing a second surface of the n-type contact layer having the active layer formed there over, wherein the supporting semiconductor layer includes the at least one ferromagnetic domain.

8. The optoelectronic semiconductor device of claim 1, wherein the p-type contact layer includes the at least one ferromagnetic domain.

9. The optoelectronic semiconductor device of claim 1, wherein the at least one ferromagnetic domain comprises an iron-based alloy.

10. The optoelectronic semiconductor device of claim 1, wherein the at least one ferromagnetic domain comprises a ferromagnetic material with a relative magnetic permeability of at least 20% of iron.

11. The optoelectronic semiconductor device of claim 1, wherein the at least one ferromagnetic domain comprises a magnetized domain.

12. The optoelectronic semiconductor device of claim 1, further comprising a pair of electrodes formed over a side of the semiconductor structure.

13. An optoelectronic semiconductor device, comprising:
a substrate;
a semiconductor structure formed over the substrate, including an n-type contact layer, an active layer formed over the n-type contact layer, and a p-type contact layer formed over the active layer;
a metallic contact to the semiconductor structure located on the substrate about the semiconductor structure; and
at least one ferromagnetic domain formed over one of the substrate, the metallic contact, or the semiconductor structure.

14. A method, comprising:
fabricating an optoelectronic semiconductor device, wherein the optoelectronic semiconductor device comprises:
a semiconductor structure including: a substrate; an n-type contact layer formed over the substrate; an active layer formed over the n-type contact layer;
and a p-type contact layer formed over the active layer; and
at least one ferromagnetic domain located on the semiconductor structure.

15. The method of claim 14, wherein the at least one ferromagnetic domain is formed about the structure by one of evaporation, sputtering, soldering, gluing, deposition and embedding.

16. The method of claim 14, further comprising:
placing the optoelectronic semiconductor device in proximity to a magnetic force;
guiding the optoelectronic semiconductor device over a pair of spaced electrodes with the magnetic force; and
releasing the optoelectronic semiconductor device from the magnetic force for placement onto the pair of spaced electrodes.

17. The method of claim 16, further comprising positioning a magnetic strip in parallel with the pair of spaced electrodes, wherein the guiding comprises aligning the at least one ferromagnetic domain of the optoelectronic semiconductor device with the magnetic strip.

18. The method of claim 17, wherein the releasing comprises releasing the optoelectronic semiconductor device from the magnetic force in response to an alignment of the at least one ferromagnetic domain to the magnetic strip.

19. The method of claim 16, wherein the releasing comprises turning off the magnetic force.

20. The method of claim 16, wherein the guiding comprises moving the optoelectronic semiconductor device from a first position to a second position having the pair of spaced electrodes with an electromagnet.
